(19) United States
(12) Patent Application Publication
(10) Pub. No.: US 2026/0133363 A1
(43) Pub. Date: May 14, 2026

(54) PHOTONIC INTEGRATED APPARATUS INCLUDING GERMANIUM

(71) Applicant: SAMSUNG ELECTRONICS CO., LTD., Suwon-si (KR)

(72) Inventors: Chanwook BAIK, Suwon-si (KR); Youngzoon YOON, Suwon-si (KR); Kyungsang CHO, Suwon-si (KR); Joohun HAN, Suwon-si (KR)

(73) Assignee: SAMSUNG ELECTRONICS CO., LTD., Suwon-si (KR)

(21) Appl. No.: 19/246,109

(22) Filed: Jun. 23, 2025

(30) Foreign Application Priority Data
Nov. 13, 2024 (KR) 10-2024-0161338

(51) Int. Cl. G02B 6/12; G02B 6/122; H10F 30/227; H10F 39/10

(52) U.S. Cl. CPC G02B 6/12004; G02B 6/1228; H10F 30/227; H10F 39/103; G02B 2006/12061; G02B 2006/12123; G02B 2006/1213

(57) ABSTRACT

A photonic integrated apparatus is provided. The photonic integrated apparatus includes a first semiconductor layer including silicon, a second semiconductor layer including germanium, provided on the first semiconductor layer, and configured to generate a photocurrent based on light incident onto the first semiconductor layer, a conductive layer having a Schottky junction structure with the second semiconductor layer, and a tunneling barrier layer between the second semiconductor layer and the conductive layer.

### CROSS-REFERENCE TO RELATED APPLICATION

This application is based on and claims priority under 35 U.S.C. § 119 to Korean Patent Application No. 10-2024-0161338, filed on Nov. 13, 2024, in the Korean Intellectual Property Office, the disclosure of which is incorporated by reference herein in its entirety.

### BACKGROUND

### 1. Field

The disclosure relates to a photonic integrated apparatus, and more particularly, to a photonic integrated apparatus including a photodetector and a waveguide.

### 2. Description of the Related Art

Photonic integrated circuits or photonic integrated apparatuses in which optical elements are integrated may be used in various optical sensors or optical connection fields. Examples of optical elements used in photonic integrated apparatuses include a light source that converts electrical energy into optical energy, an optical modulator that modulates light, a waveguide that transmits an optical signal, an optical antenna or an optical coupler that transmits light from inside a waveguide to the outside of a photonic integrated circuit chip or receives external light into a waveguide, and a photodetector that converts optical energy into electrical energy.

In general, photonic integrated circuits are based on silicon. Silicon-based optical sensors may not absorb photons with energies lower than the bandgap energy of silicon (˜1.12 eV). Therefore, there is a need for a device capable of sensing light in the infrared band.

### SUMMARY

One or more embodiments of the present disclosure provide an optical integrated apparatus including a silicon-based optical waveguide and a germanium-based photodetector.

Further, one or more embodiments of the present disclosure provide a photonic integrated apparatus including a photodetector capable of reducing dark current.

According to an aspect of the disclosure, a photonic integrated apparatus includes a first semiconductor layer including silicon, a second semiconductor layer including germanium, provided on the first semiconductor layer, and configured to generate a photocurrent based on light incident onto the first semiconductor layer, a conductive layer having a Schottky junction structure with the second semiconductor layer, and a tunneling barrier layer between the second semiconductor layer and the conductive layer.

In addition, the second semiconductor layer may be entirely doped with a same type of dopant as the first semiconductor layer or may be undoped.

In addition, a doping concentration of the second semiconductor layer may be less than a doping concentration of the first semiconductor layer.

In addition, a contact area between the conductive layer and the tunneling barrier layer may be less than a contact area between the tunneling barrier layer and the second semiconductor layer.

In addition, the second semiconductor layer may narrow in a direction from the second semiconductor layer toward the conductive layer.

In addition, the tunneling barrier layer may surround at least a portion of a side surface of the second semiconductor layer.

In addition, the conductive layer may include a conductive via.

In addition, the conductive layer may include a first conductive layer covering a plurality of surfaces of the tunneling barrier layer and a second conductive layer arranged on a portion of a surface of the first conductive layer.

In addition, a contact area between the first conductive layer and the tunneling barrier layer may be substantially equal to a contact area between the tunneling barrier layer and the second semiconductor layer.

In addition, the first semiconductor layer may include a lightly doped region and a first doped region and a second doped region apart from each other with the lightly doped region therebetween.

In addition, the lightly doped region may overlap the second semiconductor layer in a direction in which the second semiconductor layer is stacked on the first semiconductor layer.

In addition, a same voltage may be applied to the first doped region and the second doped region.

In addition, the second semiconductor layer may include at least one of Ge or GeₓSn₁₋ₓ (0<x<1).

In addition, the conductive layer may include at least one of a metal, an alloy, a metal oxide, a metal nitride, or a silicide.

In addition, a difference between a conduction band energy level of the tunneling barrier layer and an electron affinity of the second semiconductor layer may be less than or equal to 0.5 eV.

In addition, a bandgap energy of the tunneling barrier layer may be greater than a bandgap energy of the second semiconductor layer.

In addition, a bandgap energy of the tunneling barrier layer may be greater than or equal to 2 eV.

In addition, a thickness of the tunneling barrier layer may be greater than or equal to 1 nm.

In addition, the tunneling barrier layer may include at least one of a metal oxide or a silicon oxide.

In addition, the metal oxide may include at least one of TiO₂, TiO₂₋ₓ (0<x<1), TiO, Ti₂O, Ti₃O, Ti₂O₃, TiₙO₂ₙ₋₁ (where n is an integer from 3 to 9), SnO₂, ZnO, WO₃, Nb₂O₅, BaSnO₃, Zn₂SnO₄, SrTiO₃, BaTiO₃, Zn₂Ti₃O₈, SiO₂, Al₂O₃, HfO₂, MgO, MoO₃, Fe₂O₃, Ta₂O₅, TaON, or In₂O₃.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a photonic integrated apparatus according to an embodiment;

FIG. 2 is a cross-sectional view taken along line A-A′ of the photonic integrated apparatus of FIG. 1;

FIGS. 3A, 3B, and 3C are diagrams illustrating photonic integrated apparatuses according to some embodiments;

FIG. 4 is a diagram illustrating a photonic integrated apparatus including a plurality of conductive layers, according to an embodiment;

FIG. 5 is an energy band diagram when no bias voltage is applied to the photonic integrated apparatus of FIG. 4;

FIG. 6 is an energy band diagram when a reverse bias voltage is applied to the photonic integrated apparatus of FIG. 4;

FIG. 7 is an energy band diagram of a photonic integrated apparatus including a first semiconductor layer and a second semiconductor layer each doped with a p-type dopant and illustrates a state in which no bias voltage is applied thereto;

FIG. 8 is an energy band diagram of a photonic integrated apparatus including a first semiconductor layer and a second semiconductor layer each doped with a p-type dopant and illustrates a state in which a reverse bias voltage is applied thereto;

FIGS. 9A, 9B, and 9C are diagrams illustrating photonic integrated apparatuses each including a plurality of conductive layers, according to some embodiments;

FIG. 10 shows measuring results of current-voltage (I-V) characteristics of a photonic integrated apparatus with respect to a thickness of a tunneling barrier layer, according to an embodiment; and

FIG. 11 is a block diagram schematically illustrating an optical communication system including a photonic integrated apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments are described in detail with reference to the accompanying drawings. Embodiments described herein are only examples and various modifications may be made thereto from these embodiments. In the following drawings, the same reference numerals denote the same elements, and the size of each element in the drawings may be exaggerated for clarity and convenience of explanation.

Hereinafter, the terms “above” or “on” may include not only those that are directly on in a contact manner, but also those that are above in a non-contact manner.

The terms such as “first,” “second,” etc. may be used to describe various elements, but are only used to distinguish one element from another. These terms are not intended to limit different materials or structures of the elements.

The singular forms as used herein are intended to include the plural forms as well unless the context clearly indicates otherwise. It will be understood that the terms “comprise,” “include,” or “have” as used herein specify the presence of stated elements, but do not preclude the presence or addition of one or more other elements.

Also, the terms such as “unit” and “module” described in the specification mean units that process at least one function or operation, and may be implemented as hardware, software, or a combination of hardware and software.

Specific implementations described in the present embodiments are only examples and do not limit the scope of the disclosure in any way. For the sake of conciseness of the specification, descriptions of conventional electronic components, control systems, software, and other functional aspects of the systems may be omitted. In addition, connecting lines or connecting members illustrated in the drawings are intended to represent exemplary functional connections and/or physical or circuit connections. In an actual device, it may appear as a variety of alternative or additional functional, physical, or circuit connections.

The use of the term “the” and similar demonstratives may correspond to both the singular and the plural.

Operations constituting methods may be performed in any suitable order unless otherwise indicated herein or otherwise clearly contradicted by context. Also, the use of all illustrations or illustrative terms (for example, etc.) in the embodiments is simply to describe the technical ideas in detail, and the scope of the disclosure is not limited by the illustrations or illustrative terms unless they are limited by claims.

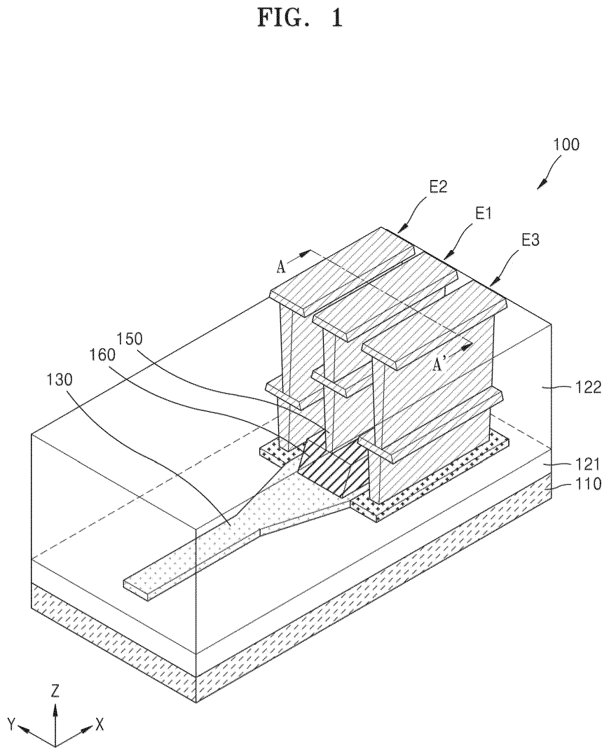

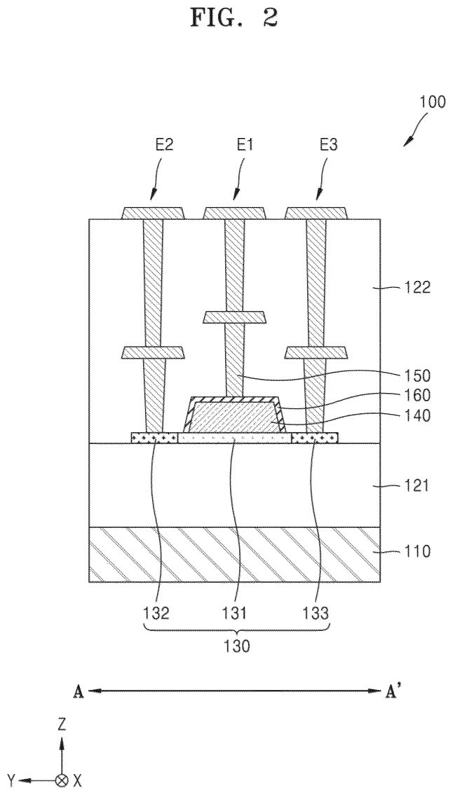

FIG. 1 is a diagram illustrating a photonic integrated apparatus 100 according to an embodiment, and FIG. 2 is a cross-sectional view taken along line A-A′ of the photonic integrated apparatus 100 of FIG. 1. The photonic integrated apparatus 100 may be included an optical connect, an optical communication apparatus, but its applications of the photonic integrated apparatus 100 are not limited thereto.

Referring to FIGS. 1 and 2, the photonic integrated apparatus 100 may include a substrate 110, a first dielectric layer 121 arranged on the substrate 110, a first semiconductor layer 130 including silicon and arranged on the first dielectric layer 121, a second semiconductor layer 140 including germanium and arranged on the first semiconductor layer 130, a conductive layer 150 having a Schottky junction structure with the second semiconductor layer 140, and a tunneling barrier layer 160 arranged between the second semiconductor layer 140 and the conductive layer 150.

A portion of the first semiconductor layer 130 may act as a waveguide, and the first semiconductor layer 130, the second semiconductor layer 140, the conductive layer 150, and the tunneling barrier layer 160 may constitute a photodetector. In FIGS. 1 and 2, a waveguide and a photodetector are illustrated as optical elements of the photonic integrated apparatus 100, but the disclosure is not limited thereto. The photonic integrated apparatus 100 may include various optical elements other than the waveguide and the photodetector. For example, the photonic integrated apparatus 100 may also include a light source, an optical amplifier, an optical modulator, an optical coupler, or the like.

The substrate 110 may include a semiconductor material. For example, the substrate 110 may be a silicon (Si) substrate 110. However, the material of the substrate 110 is not necessarily limited to silicon, and other wafer materials used in semiconductor manufacturing processes may be used as the material of the substrate 110.

The first dielectric layer 121 may be arranged on the substrate 110. The first dielectric layer 121 may include an oxide. For example, the first dielectric layer 121 may include silicon oxide (SiO₂), but the disclosure is not necessarily limited thereto. The first dielectric layer 121 may include, in addition to silicon oxide, at least one of an insulating silicon compound or an insulating metal compound. The insulating silicon compound may include, for example, silicon nitride (SiₓN_{y}), silicon oxynitride (SiON), or the like.

The first semiconductor layer 130 may be arranged on the first dielectric layer 121. Because the first semiconductor layer 130 functions as a waveguide, the first semiconductor layer may include a material having a refractive index greater than a refractive index of the first dielectric layer 121. For example, the first semiconductor layer 130 may include at least one of silicon or nitride. The substrate 110, the first dielectric layer 121, and the first semiconductor layer 130 may be formed as one silicon-on-insulator (SOI) substrate 110. For example, the first semiconductor layer 130 may be formed by partially patterning a silicon layer on the SOI substrate 110.

The first semiconductor layer 130 may be doped with a p-type dopant or an n-type dopant. The p-type dopant may be B, Al, Ga, In, or Te, and the n-type dopant may be P, As, or Sb. The first semiconductor layer 130 may include a lightly doped region 131 in which a doping concentration of the dopant is relatively low and heavily doped regions 132 and 133 in which a doping concentration of the dopant is relatively high. The lightly doped region 131 may be arranged to extend in a first direction (e.g., an X-axis direction) and may include a tapered region, a width of which increases toward the second semiconductor layer 140. Because light travels in the first direction within the lightly doped region 131, the lightly doped region 131 may act as a waveguide. The heavily doped regions 132 and 133 may include a first heavily doped region 132 and a second heavily doped region 133 apart from each other with the lightly doped region 131 therebetween.

The second semiconductor layer 140 may be arranged on the first semiconductor layer 130. The second semiconductor layer 140 may be arranged on the first semiconductor layer 130 in a second direction (e.g., a Z-axis direction) perpendicular to the first direction. The second semiconductor layer 140 may be arranged to overlap the lightly doped region 131 of the first semiconductor layer 130 in the second direction (e.g., in the Z-axis direction) and not overlap the heavily doped regions 132 and 133, but the disclosure is not limited thereto. The second semiconductor layer 140 may become narrower in the second direction, that is, toward the conductive layer 150. The second semiconductor layer 140 may have a frustum shape (e.g., a cone frustum or a pyramid frustum), which has a truncated top that tapers from a larger bottom base to a smaller top base. A photocurrent generated in the second semiconductor layer 140 may effectively move to the conductive layer 150.

The second semiconductor layer 140 may include at least one of Ge or GeₓSn₁₋ₓ (0<x<1). The second semiconductor layer 140 may be a semiconductor entirely doped with the same type of dopant as the first semiconductor layer 130, or may be an undoped intrinsic semiconductor. When the second semiconductor layer 140 is doped with a dopant, the doping concentration of the second semiconductor layer 140 may be less than the doping concentration of the first semiconductor layer 130. For example, the doping concentration of the second semiconductor layer 140 may be less than the doping concentration of the lightly doped region 131 of the first semiconductor layer 130. Alternatively, the doping concentration of the second semiconductor layer 140 may be 10¹³ to 10¹⁸/cm³.

Conventional silicon-based photodetectors may not absorb photons with energies lower than the bandgap energy of silicon. Silicon photodiodes may be mainly used as visible-light sensors because the silicon photodiodes have high quantum efficiency in a visible-light band (a wavelength of 400 nm to 700 nm). However, because light absorption does not occur well in silicon in a near infrared (NIR) band (a wavelength of 700 nm to 1,600 nm) applicable to optical communications, silicon photodetectors may be difficult to use as optical sensors in photonic integrated circuits. However, because germanium (Ge) has a lower bandgap energy than silicon, light absorption may occur in a wavelength of 800 nm to 3,000 nm, for example, 800 nm to 1,700, and germanium (Ge) may be applied to sensors.

The conductive layer 150 may have a Schottky junction structure with the second semiconductor layer 140. In an embodiment, the conductive layer 150 may include a conductive via passing through a second dielectric layer 122. The second dielectric layer 122 may also include an insulating material. The second dielectric layer 122 may include an insulating material that is identical to a material of the first dielectric layer 121, or may include a material that is different from a material of the first dielectric layer 121. The conductive layer 150 may include a metal, an alloy, a metal nitride, a silicide, or the like. Examples of the metal may include Au, Al, Ag, Cu, Pt, Ni, W, Ti, Mo, Ru, Ge, Ta, Hf, Nb, Zr, or V. Examples of the alloy may include AlNd. Examples of the metal nitride may include TiN, AlN, TaN, Ta₂N, Ta₃N₅, W₂N, WN, or WN₂. Examples of the silicide may include TiSi, TiSi₂, Ti₅Si₃, VSi₂, FeSi₂, CoSi₂, PtSi, Pt₂Si, NiSi, NiSi₂, Ni₂Si, Cu₃Si, YSi, ZrSi, NbSi₂, MoSi₂, PdSi, Pd₂Si, ErSi, YbSi, YbSi₂, ZrSi₂, HfSi, HfSi₂, TaSi, TaSi₂, NbSi, NbSi₂, ZrSi, ZrSi₂, VSi, VSi₂, WSi, WSi₂, GeSi, OsSi, IrSi, IrSi₃, AlSi, CuSi RuSi, or Ru₂Si₃.

The photodetector using a Schottky junction according to an embodiment may be driven at a lower voltage than a silicon P-N junction structure when a reverse voltage is applied thereto, and may switch between a forward bias voltage and a reverse bias voltage at a high speed, which enables high-speed switching. In addition, the photodetector using a Schottky junction according to an embodiment has a simpler manufacturing process than a P-N junction structure, which reduces mass production costs.

By appropriately selecting the work functions and energy levels of the second semiconductor layer 140 and the conductive layer 150, a photocurrent may be generated with high quantum efficiency. Light passing through the lightly doped region 131 of the first semiconductor layer 130 may be incident on at least one of the second semiconductor layer 140 or the conductive layer 150 by optical coupling. For example, at least a portion of light may be incident on at least one of the second semiconductor layer 140 or the conductive layer 150 by at least one of evanescent coupling or butt coupling.

When the energy of light incident on the second semiconductor layer 140 is greater than the bandgap energy of germanium (Ge), a photocurrent may be generated with high efficiency by interband transition within the second semiconductor layer 140. When the energy of light incident on the conductive layer 150 is greater than the Schottky barrier height, hot carriers may be generated in the conductive layer 150 by an internal photoemission effect, and thus, a photocurrent may flow. At this time, the amount of the photocurrent generated in the conductive layer 150 may be smaller than the amount of the photocurrent generated in the second semiconductor layer 140. Because the photocurrent is generated by the two effects, high quantum efficiency may be achieved.

On the other hand, in the photodetector using a Schottky barrier, the Schottky barrier structure essentially has an energy band diagram that is sharply tilted by energy band bending. This may cause dark current, or leakage current, to occur due to quantum mechanical tunneling. That is, carriers having energy lower than the Schottky barrier height may pass through the Schottky barrier due to field emission that occurs between the conductive layer 150 and the second semiconductor layer 140. This may correspond to dark current in the absence of incident light and may generate noise in the photodetector or the photonic integrated apparatus 100 including the photodetector.

In addition, when the second semiconductor layer 140 including germanium is grown on the first semiconductor layer 130 including silicon, a lattice mismatch may occur due to a difference between a lattice constant of silicon and a lattice constant of germanium. The lattice mismatch is about 4.3%, which may introduce defects in the second semiconductor layer 140. These defects may lead to dark current generation. The dark current may cause noise in the photonic integrated apparatus 100 and may cause problems of lowering optical responsivity. Furthermore, doping the second semiconductor layer 140 with a dopant may introduce additional defect sites and therefore may increase the dark current. Therefore, to improve the performance of the photodetector or the photonic integrated apparatus 100 including the photodetector, it is necessary to suppress dark current as much as possible.

The photonic integrated apparatus 100 according to an embodiment may further include the tunneling barrier layer 160 arranged between the conductive layer 150 and the second semiconductor layer 140. The contact area between the conductive layer 150 and the tunneling barrier layer 160 may be less than the contact area between the tunneling barrier layer 160 and the second semiconductor layer 140.

The tunneling barrier layer 160 may reduce leakage current caused by quantum mechanical tunneling by increasing the thickness of the Schottky barrier structure while having little or no effect on the Schottky barrier height. To lessen the effect on the height of the Schottky barrier, the tunneling barrier layer 160 may include a material having a conduction band energy level similar to an electron affinity of the second semiconductor layer 140. That is, the tunneling barrier layer 160 may include a material having a conduction band energy level similar to a conduction band energy level of the second semiconductor layer 140. For example, the difference between the conduction band energy level of the tunneling barrier layer 160 and the conduction band energy level (i.e., the electron affinity) of the second semiconductor layer 140 may be 0.5 eV or less.

In addition, to reduce or prevent dark current occurring due to separation of electron-hole pairs by light having low energy, the bandgap energy of the tunneling barrier layer 160 may be greater than the bandgap energy of the second semiconductor layer 140. For example, the bandgap energy of the tunneling barrier layer 160 may be greater than the bandgap energy of the second semiconductor layer 140 by 2 eV or more.

The tunneling barrier layer 160 may include at least one of a metal oxide or a silicon oxide having a wide bandgap energy. For example, the tunneling barrier layer 160 may be an oxide including at least one of titanium (Ti), tin (Sn), zinc (Zn), tungsten (W), niobium (Nb), barium (Ba), strontium (Sr), aluminum (Al), hafnium (Hf), magnesium (Mg), molybdenum (Mo), iron (Fe), tantalum (Ta), or indium (In). Specifically, the tunneling barrier layer 160 may include at least one of TiO₂, TiO₂₋ₓ (0<x<1), TiO, Ti₂O, Ti₃O, Ti₂O₃, TiₙO₂ₙ₋₁ (where n is an integer from 3 to 9), SnO₂, ZnO, WO₃, Nb₂O₅, BaSnO₃, Zn₂SnO₄, SrTiO₃, BaTiO₃, Zn₂Ti₃O₈, SiO₂, Al₂O₃, HfO₂, MgO, MoO₃, Fe₂O₃, Ta₂O₅, TaON, or In₂O₃.

The thickness of the tunneling barrier layer 160 may be determined so as to reduce or prevent dark current. The thickness of the tunneling barrier layer 160 may be about 1 nm to about 30 nm, or about 3 nm to about 30 nm. When the thickness of the tunneling barrier layer 160 is greater than 30 nm, it may be difficult for carriers to move beyond the tunneling barrier layer 160 even in a normal state. To ensure carrier mobility, the thickness of the tunneling barrier layer 160 may be, for example, 10 nm or less.

The photonic integrated circuit according to an embodiment may include a first electrode E1, a second electrode E2, and a third electrode E3 configured to measure an electrical signal (e.g., current) generated in the Schottky junction structure. The first electrode E1 may be electrically connected to the conductive layer 150, the second electrode E2 may be connected to the first heavily doped region 132 of the first semiconductor layer 130, and the third electrode E3 may be connected to the second heavily doped region 133 of the first semiconductor layer 130. As illustrated, the conductive layer 150 may be a component of the first electrode E1.

A common voltage, for example, 0 V, may be applied to the first heavily doped region 132 and the second heavily doped region 133 through the second electrode E2 and the third electrode E3. The first electrode E1, the second electrode E2, and the third electrode E3 may include at least one of a conductive via or a pad.

In an embodiment, a metal layer, a TiO₂-based layer, a Ge-based layer, and a Si-based layer may be formed on Si-based waveguide, where the TiO₂-based layer may be used as the tunneling barrier layer 160, the metal layer and the Ge-based layer may form the Schottky junction structure, and the metal layer is connected to an electrode. The TiO₂-based layer in the Schottky junction structure may reduce dark current and improve quantum efficiency in a light detection. The photonic integrated apparatus 100 may detect an infrared (IR) light in a range from 1,100 nm to 1,600 nm, but the light detection range of the photonic integrated apparatus 100 is not limited to the IR spectrum and may include other light ranges as well. The photonic integrated apparatus 100 may sense horizontally incident IR light through a silicon waveguide (e.g., the first semiconductor layer 130) positioned on the substrate 110. The IR light propagates through the silicon waveguide and is coupled into the Ge-based layer (e.g., the second semiconductor layer 140). The photonic integrated apparatus 100 may also include a via structure and electrode structure (e.g., electrodes E1, E2, and E3) for photogenerated current sensing on the upper part of the substrate 110. In an embodiment, the inclusion of an oxide semiconductor layer, such as the TiO₂-based layer, between the Ge-based layer and an upper electrode layer (e.g., the conductive layer 150 and the electrode E1) may reduce dark current without compromising quantum efficiency in the IR spectrum.

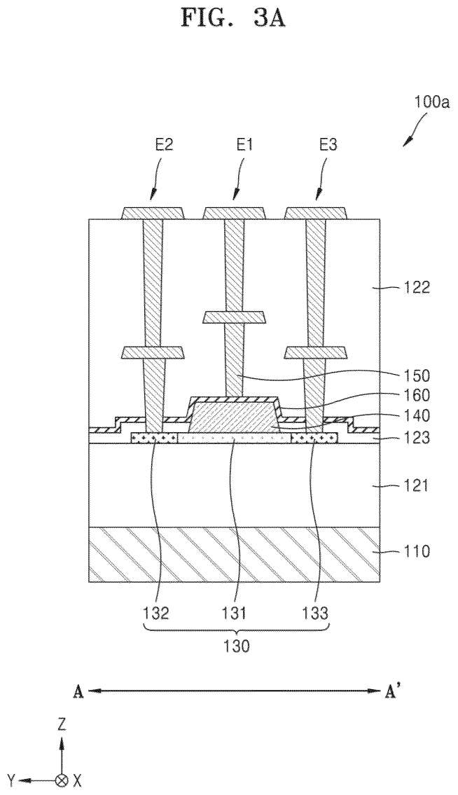

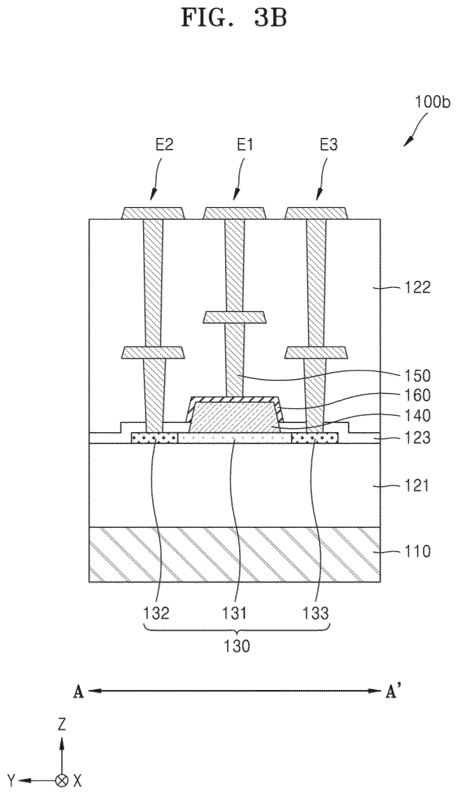

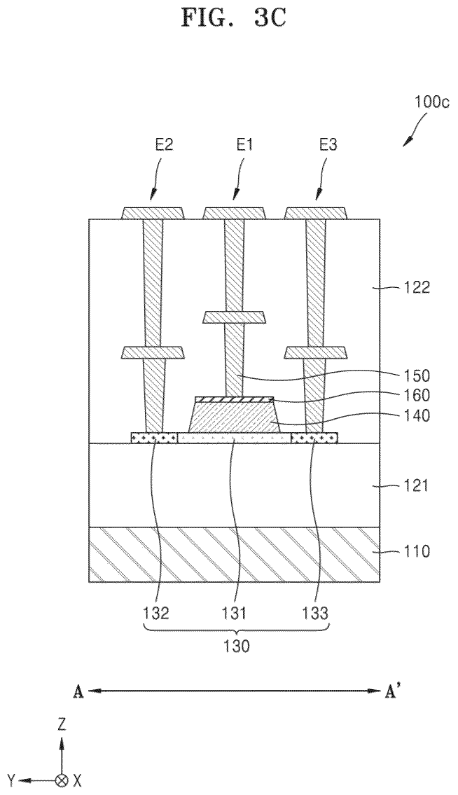

FIGS. 3A, 3B, and 3C are diagrams illustrating photonic integrated apparatuses 100a, 100b, and 100c according to some embodiments. Comparing FIG. 2 with FIG. 3A, the photonic integrated apparatus 100a of FIG. 3A may further include a third dielectric layer 123 that covers a first semiconductor layer 130. The third dielectric layer 123 may not cover the second semiconductor layer 140, leaving the second semiconductor layer 140 exposed, although the second semiconductor layer 140 may be covered by another layer. The third dielectric layer 123 may include an oxide. For example, the third dielectric layer 123 may include silicon oxide (SiO₂), but the disclosure is not necessarily limited thereto. A tunneling barrier layer 160 may be arranged on the second semiconductor layer 140 and the third dielectric layer 123. The photonic integrated apparatus 100a of FIG. 3A may reduce the number of process masks, which facilitates a process.

The tunneling barrier layer 160 may be arranged only on the upper surface and the side surfaces of the second semiconductor layer 140, as illustrated in FIG. 3B, or may be arranged only on the upper surface of the second semiconductor layer 140, as illustrated in FIG. 3C. The tunneling barrier layer 160 may have various shapes when the tunneling barrier layer 160 is arranged between the second semiconductor layer 140 and the conductive layer 150 and the contact area between the second semiconductor layer 140 and the tunneling barrier layer 160 is greater than the contact area between the tunneling barrier layer 160 and the conductive layer 150.

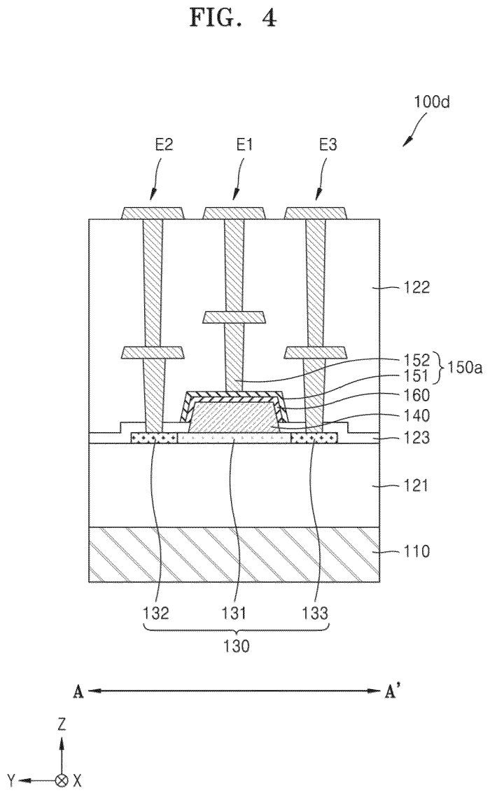

FIG. 4 is a diagram illustrating a photonic integrated apparatus 100d including a plurality of conductive layers, according to an embodiment. Comparing FIG. 3B and FIG. 4, a conductive layer 150a of the photonic integrated apparatus 100d of FIG. 4 may include a first conductive layer 151 surrounding a plurality of surfaces of a second semiconductor layer 140 and a second conductive layer 152 arranged on some surfaces of the first conductive layer 151. For example, the first conductive layer 151 may be arranged on the upper surface of the tunneling barrier layer 160 and a portion of the side surface of of the tunneling barrier layer 160, and may have a Schottky junction structure with the second semiconductor layer 140. The second conductive layer 152 may be spatially separated from the second semiconductor layer 140 and may form a Schottky junction structure through the first conductive layer 151 and the tunneling barrier layer 160.

A tunneling barrier layer 160 may be arranged between the second semiconductor layer 140 and the conductive layer 150a. For example, the contact area between the first conductive layer 151 and the tunneling barrier layer 160 may be substantially equal to the contact area between the tunneling barrier layer 160 and the second semiconductor layer 140. The contact area between the first conductive layer 151 and the second conductive layer 152 may be less than the contact area between the first conductive layer 151 and the tunneling barrier layer 160. The light detection efficiency may be improved by increasing the Schottky junction area between the second semiconductor layer 140 and the first conductive layer 151.

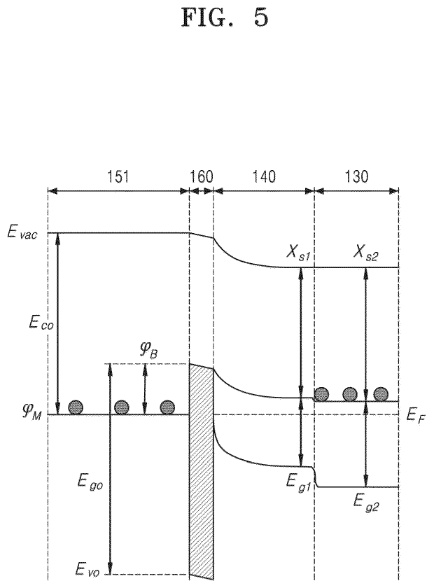

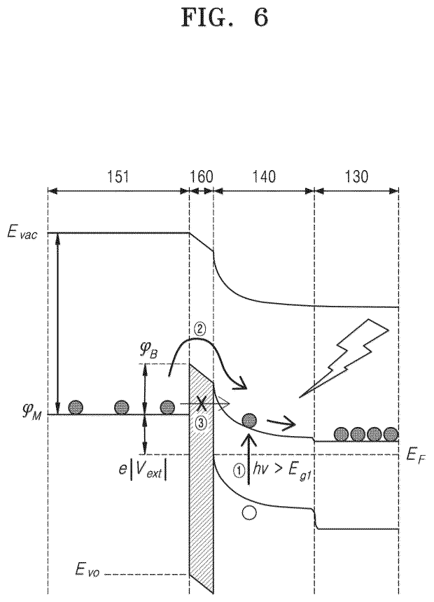

FIG. 5 is an energy band diagram when no bias voltage is applied to the photonic integrated apparatus 100d of FIG. 4, and FIG. 6 is an energy band diagram when a reverse bias voltage is applied to the photonic integrated apparatus 100d of FIG. 4. The definitions of symbols disclosed in FIGS. 5 and 6 are as follows.

φ_{M}: work function of the first conductive layer 151

φ_{B}: Schottky barrier height

E_{vac}: energy level of vacuum

E_{co}: conduction band energy level of the tunneling barrier layer 160

Eᵥₒ: valence band energy level of the tunneling barrier layer 160

E_{go}: bandgap energy of the tunneling barrier layer 160

E_{c}: conduction band energy level of the second semiconductor layer 140

Eᵥ: valence band energy level of the second semiconductor layer 140

E_{F}: Fermi energy level of the n-type second semiconductor layer 140

E_{g1}: bandgap energy of the n-type second semiconductor layer 140

E_{g2}: bandgap energy of the n-type first semiconductor layer 130

χₛ₁: electron affinity of the n-type second semiconductor layer 140

χₛ₂: electron affinity of the n-type first semiconductor layer 130

e□Vxt□: energy due to reverse bias voltage

hν: energy of incident light

For example, in FIGS. 5 and 6, the first semiconductor layer 130 was formed of silicon (Si) doped with an n-type dopant, the second semiconductor layer 140 was formed of germanium (Ge) doped with an n-type dopant, the first conductive layer 151 was formed of TiN, and the tunneling barrier layer 160 was formed of TiO₂. In this case, the bandgap energy E_{g} of germanium (Ge) is 0.67 eV, the electron affinity χₛ₁ of germanium (Ge) is 4.0 eV, and the work function φ_{M} of TiN is 4.66 eV. The Schottky barrier height φ_{B}=φ_{M}−χ_{S1}=4.66−4.0=0.66 eV. Because the second semiconductor layer 140 is formed of germanium (Ge) doped with an n-type dopant, the majority carrier may be electrons.

When the reverse bias voltage is applied, the Fermi energy level E_{F} of the second semiconductor layer 140 may be lowered by the energy e□Vext□ provided by the bias voltage, as illustrated in FIG. 6. Light passing through the first semiconductor layer 130 may be incident on at least one of the second semiconductor layer 140 or the first conductive layer 151 by optical coupling. The optical coupling may be at least one of evanescent coupling or butt coupling. When the Schottky barrier height φB is as low as about 0.66 eV and the Schottky barrier is thin, a portion of light incident on the second semiconductor layer 140 may also be absorbed in the first conductive layer 151.

As indicated by reference symbol \textcircled{1} in FIG. 6, when the energy of light incident on the second semiconductor layer 140 is greater than the bandgap energy of the second semiconductor layer 140 (hν>E_{g}), a photocurrent caused by interband transition may flow.

In addition, as indicated by reference symbol \textcircled{2} in FIG. 6, when the energy of light incident on the first conductive layer 151 is higher than the Schottky barrier height φ_{B} formed between the first conductive layer 151 and the second semiconductor layer 140 (hν>φ_{B}), light absorption may occur in the first conductive layer 151 and hot carriers may be formed by an internal quantum emission effect, allowing a photocurrent to flow. The photocurrent caused by the internal quantum emission effect is relatively less efficient than the photocurrent caused by the interband transition.

In FIG. 6, in a case where there is no tunneling barrier layer 160, even when there is no incident light, some of the majority carriers, i.e., electrons, having energy lower than the Schottky barrier height may penetrate through the Schottky barrier through quantum mechanical tunneling and move from the first conductive layer 151 to the second semiconductor layer 140. Due to this, dark current may occur.

The photonic integrated apparatus 100d according to an embodiment may include the tunneling barrier layer 160 arranged between the first conductive layer 151 and the second semiconductor layer 140. The electron affinity χ_{S1} of Ge included in the second semiconductor layer 140 is about 4.05 eV. The conduction band energy level E_{co} of TiO₂ included in the tunneling barrier layer 160 is around 4.0 eV from the energy level of vacuum, which is almost the same. Therefore, the tunneling barrier layer 160 has little effect on the Schottky barrier height between the first conductive layer 151 and the second semiconductor layer 140. On the other hand, the valence band energy level Eᵥₒ of TiO₂ is −7.2 eV, and the bandgap energy E_{go} of TiO₂ is about 3.2 eV, which is greater than 0.67 eV that is the bandgap energy E_{g1} of germanium (Ge). Therefore, TiO₂ may act as a quantum tunneling barrier and may prevent dark current, i.e., leakage current. The amount of dark current may be controlled by increasing the thickness of the tunneling barrier layer 160. That is, as indicated by reference symbol \textcircled{3} in FIG. 6, the tunneling of electrons may be reduced or prevented, and thus, dark current may be reduced or prevented.

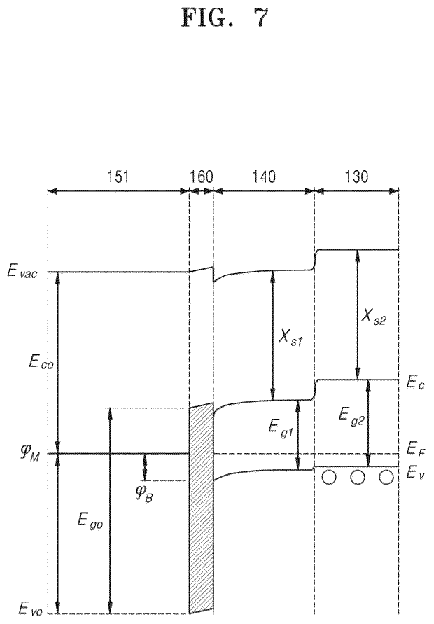

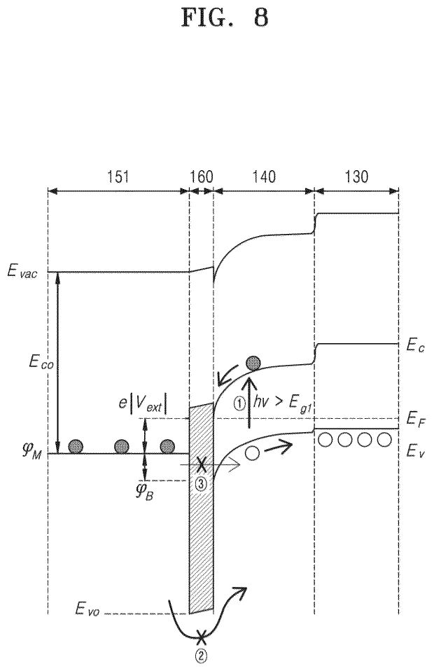

FIG. 7 is an energy band diagram of a photonic integrated apparatus including a first semiconductor layer 130 and a second semiconductor layer 140 each doped with a p-type dopant and illustrates a state in which no bias voltage is applied thereto, and FIG. 8 is an energy band diagram of a photonic integrated apparatus including a first semiconductor layer 130 and a second semiconductor layer 140 each doped with a p-type dopant and illustrates a state in which a reverse bias voltage is applied thereto. The definitions of symbols disclosed in FIGS. 7 and 8 are as follows.

φ_{M}: work function of the first conductive layer 151

φ_{B}: Schottky barrier height

E_{vac}: energy level of vacuum

E_{co}: conduction band energy level of the tunneling barrier layer 160

Eᵥₒ: valence band energy level of the tunneling barrier layer 160

E_{go}: bandgap energy of the tunneling barrier layer 160

E_{F}: Fermi energy level of the p-type second semiconductor layer 140

E_{g1}: bandgap energy of the p-type second semiconductor layer 140

E_{g2}: bandgap energy of the p-type first semiconductor layer 130

χₛ₁: electron affinity of the p-type second semiconductor layer 140

χₛ₂: electron affinity of the p-type first semiconductor layer 130

e□Vext□: energy due to reverse bias voltage

hν: energy of incident light

For example, in FIGS. 7 and 8, the first semiconductor layer 130 was formed of silicon (Si) doped with a p-type dopant, the second semiconductor layer 140 was formed of germanium (Ge) doped with a p-type dopant, the first conductive layer 151 was formed of Al, and the tunneling barrier layer 160 was formed of TiO₂. In this case, the bandgap energy E_{g} of germanium (Ge) is 0.67 eV, the electron affinity χₛ₁ of germanium (Ge) is 4.0 eV, and the work function φ_{M} of Al is 4.25 eV. The Schottky barrier height φ_{B}=E_{g}−(φ_{M}−χ_{S1})=0.67−(4.25−4.0)=0.42 eV. Because the second semiconductor layer 140 is doped with a p-type dopant, the majority carriers that generate a photocurrent may be holes.

When the reverse bias voltage is applied, the Fermi energy level E_{F} of the second semiconductor layer 140 may be raised by the energy e□Vext□ provided by the bias voltage, as illustrated in FIG. 8. Therefore, as indicated by reference symbol \textcircled{1} in FIG. 7, when the energy of light incident on the second semiconductor layer 140 is greater than the bandgap energy of the second semiconductor layer 140 (hν>E_{g1}), a photocurrent caused by interband transition may flow.

In a case where there is no tunneling barrier layer 160, when the energy of light incident on the first conductive layer 151 is higher than the Schottky barrier height φ_{B} formed between the first conductive layer 151 and the second semiconductor layer 140 (hν>φ_{B}), light absorption may occur in the first conductive layer 151 and hot carriers may be formed by an internal quantum emission effect, allowing a photocurrent to flow. However, when there is the tunneling barrier layer 160, as illustrated in FIG. 8, the Schottky barrier height increases up to the valence band energy level Eᵥₒ of the tunneling barrier layer 160, as indicated by reference symbol \textcircled{2}. Accordingly, it is very difficult for hot carriers generated by an internal quantum emission effect due to light absorption occurring in the conductive layer 151 to move beyond the tunneling barrier layer 160. On the other hand, because the conduction band energy level of the tunneling barrier layer 160 is almost similar to the electron affinity χ_{S1} of Ge included in the second semiconductor layer 140, it has little effect on the formation of a photocurrent caused by interband transition due to the energy of light incident on the second semiconductor layer 140, as indicated by reference symbol \textcircled{1}. On the other hand, the valence band energy level Eᵥₒ of TiO₂ is −7.2 eV, and the bandgap energy E_{go} of TiO₂ is about 3.2 eV, which is greater than 0.67 eV that is the bandgap energy E_{g1} of germanium (Ge). Therefore, TiO₂ may act as a quantum tunneling barrier and may prevent dark current, i.e., leakage current. The amount of dark current may be controlled by increasing the thickness of the tunneling barrier layer 160. That is, as indicated by reference symbol \textcircled{3} in FIG. 8, the tunneling of electrons may be reduced or prevented, and thus, dark current may be reduced or prevented.

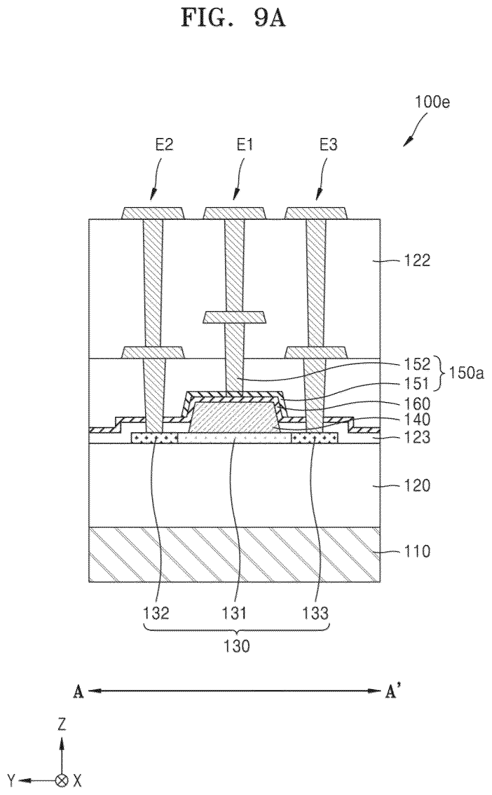

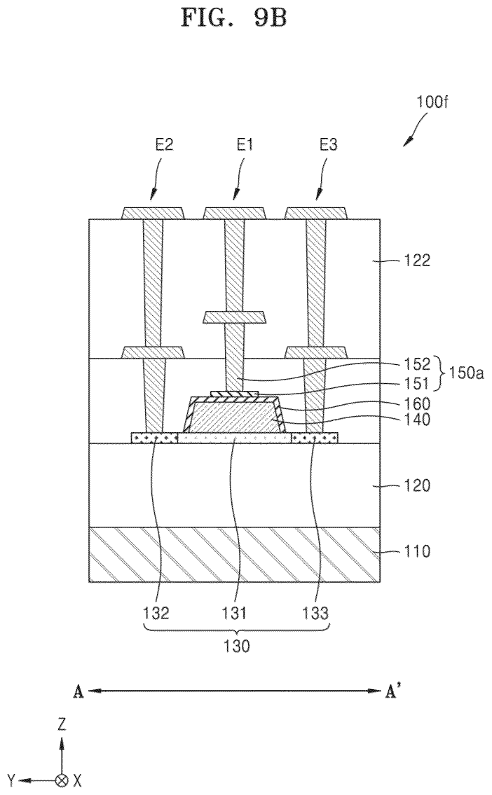

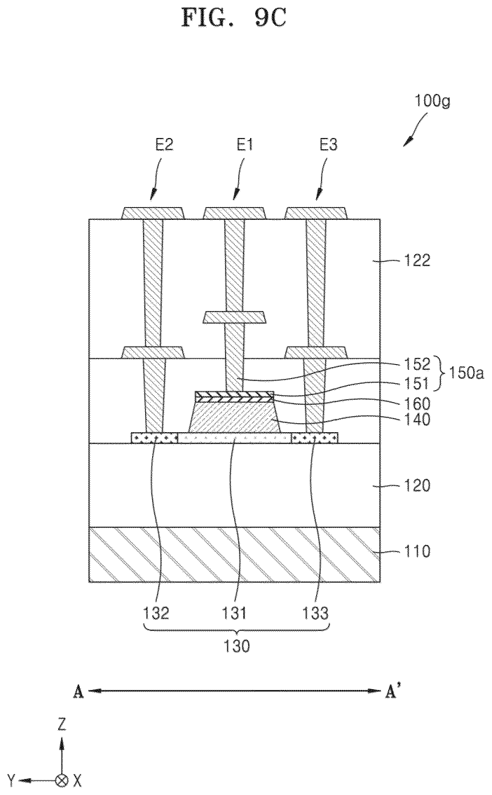

FIGS. 9A, 9B, and 9C are diagrams illustrating photonic integrated apparatuses 100 e, 100 f, and 100g each including a plurality of conductive layers, according to some embodiments. As illustrated in FIGS. 9A to 9C, a first conductive layer 151 may be arranged between a tunneling barrier layer 160 and a second conductive layer 152 and may have a Schottky junction structure with a second semiconductor layer 140.

The contact area between the first conductive layer 151 and the tunneling barrier layer 160 may be substantially equal to the contact area between the tunneling barrier layer 160 and the second semiconductor layer 140. The contact area between the first conductive layer 151 and the second conductive layer 152 may be less than the contact area between the first conductive layer 151 and the tunneling barrier layer 160. The light detection efficiency may be improved by increasing the Schottky junction area between the second semiconductor layer 140 and the first conductive layer 151.

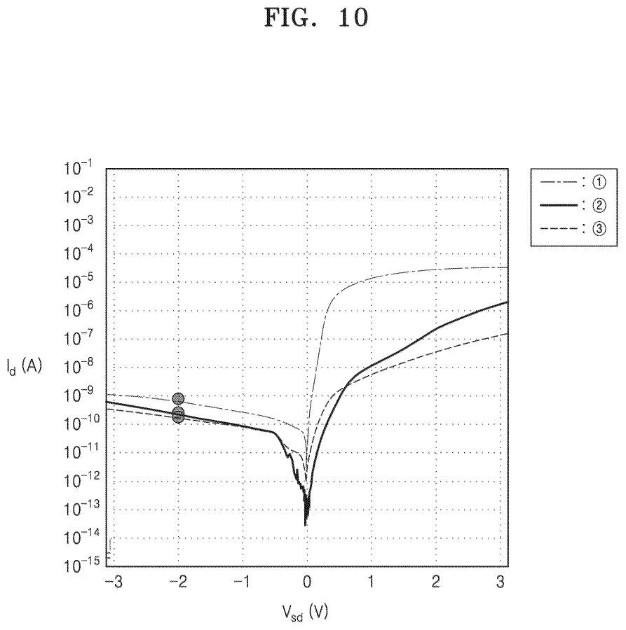

FIG. 10 shows a result of measuring current-voltage (I-V) characteristics of the photonic integrated apparatus 100 with respect to the thickness of the tunneling barrier layer 160, according to an embodiment. \textcircled{1} is the I-V characteristic of the photonic integrated apparatus 100 in which the conductive layer 150 is Schottky-joined to the second semiconductor layer 140 having an area of 2 □m×2 □m without the tunneling barrier layer 160, \textcircled{2} is the I-V characteristic of the photonic integrated apparatus 100 in which the conductive layer 150 is Schottky-joined to the second semiconductor layer 140 having an area of 2 □m×2 □m with the tunneling barrier layer 160 having a thickness of 3 nm therebetween, and \textcircled{3} is the I-V characteristic of the photonic integrated apparatus 100 in which the conductive layer 150 is Schottky-joined to the second semiconductor layer 140 having an area of 2 □m×2 □m with the tunneling barrier layer 160 having a thickness of 6 nm therebetween. In a state in which a reverse bias voltage of −2 V is applied, currents (i.e., dark current) of 0.609 nA, 0.212 nA, and 0.171 nA were detected in the respective cases. That is, the I-V characteristics \textcircled{1}, \textcircled{2}, \textcircled{3} and of the photonic integrated apparatus 100 in FIG. 10 show that, as the thickness of the tunneling barrier layer 160 increases, a dark current blocking effect also increases. However, when the thickness of the tunneling barrier layer 160 is excessively great, the second semiconductor layer 140 and the conductive layer 150 may not be Schottky-joined. Accordingly, the thickness of the tunneling barrier layer 160 may be about 30 nm or less.

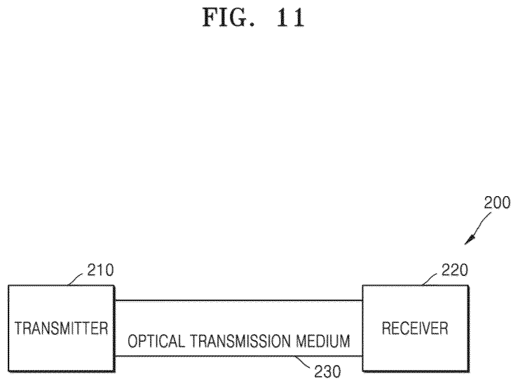

FIG. 11 is a block diagram schematically illustrating an optical communication system 200 including a photonic integrated apparatus, according to an embodiment.

Referring to FIG. 11, the optical communication system 200 may include a transmitter 210, a receiver 220, and an optical transmission medium 230 that optically connects the transmitter 210 to the receiver 220. The transmitter 210 may convert an electrical signal into an optical signal and transmit the optical signal to the optical transmission medium 230. In an example, the electrical signal may include data to be transmitted to the receiver 220 through the optical transmission medium 230. In an example, the electrical signal may be generated by the transmitter 210 itself, or may be received from an external source and transmitted from the transmitter 210 to the receiver 200. In an example, the transmitter 210 may include a device capable of electro-optical conversion and may include a driver that drives the element, but the disclosure is not limited thereto. In an example, the transmitter 210 may include a light source that is connected to the optical transmission medium 230 in a wired manner and generates an optical signal modulated according to an electrical signal.

In an example, the optical transmission medium 230 may be optically connected to the transmitter side and the receiver side in optical communication. In the case of long-range communication, the optical transmission medium 230 may include an optical fiber. In the case of short-range communication (e.g., when the transmitter side and the receiver side are included in the same device or system), the optical transmission medium 230 may include an optical waveguide, but the disclosure is not limited thereto. In an example, the optical waveguide may include a silicon waveguide, but the disclosure is not limited thereto.

In an example, the receiver 220 may include an element configured to receive an optical signal transmitted from the transmitter 210. Because the electrical signal generated by the transmitter 210 is converted into an optical signal and then transmitted to the receiver 220 through the optical transmission medium 230, the receiver 220 may include an optical detector that detects the optical signal transmitted from the optical transmission medium 230 and converts the detected optical signal into an electrical signal. In an example, the photodetector may be a photoelectric conversion device. The receiver 220 may include the photonic integrated apparatus 100, 100 a, 100 b, 100 c, 100 d, 100 f, or 100g according to an embodiment. The receiver 220 may further include a processor that processes an electrical signal generated by the photonic integrated apparatus 100, 100 a, 100 b, 100 c, 100 d, 100 f, or 100g.

According to the embodiment of the photonic integrated apparatus described above, the Schottky junction structure using germanium may be employed to detect light in the NIR and short-wavelength infrared bands. In addition, by employing the tunneling barrier layer, dark current due to quantum mechanical tunneling by low-energy majority carriers may be reduced.

According to the embodiments described above, because the photonic integrated apparatus includes a Schottky junction structure, the photonic integrated apparatus may be driven at a low voltage, compared to a general P-N junction structure or a general P-I-N junction structure, may enable high-speed switching, and may have a simple manufacturing process, thereby reducing mass production costs.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A photonic integrated apparatus comprising:
a first semiconductor layer comprising silicon, extending in a first direction, and through which light travels in the first direction;
a second semiconductor layer comprising germanium, provided on the first semiconductor layer, and configured to generate a photocurrent based on light incident onto the first semiconductor layer;
a conductive layer having a Schottky junction structure with the second semiconductor layer; and
a tunneling barrier layer between the second semiconductor layer and the conductive layer.

2. The photonic integrated apparatus of claim 1, wherein the second semiconductor layer is entirely doped with a same type of dopant as the first semiconductor layer or is undoped.

3. The photonic integrated apparatus of claim 2, wherein a doping concentration of the second semiconductor layer is less than a doping concentration of the first semiconductor layer.

4. The photonic integrated apparatus of claim 1, wherein a contact area between the conductive layer and the tunneling barrier layer is less than a contact area between the tunneling barrier layer and the second semiconductor layer.

5. The photonic integrated apparatus of claim 1, wherein the second semiconductor layer narrows in the second direction.

6. The photonic integrated apparatus of claim 1, wherein the tunneling barrier layer surrounds at least a portion of a side surface of the second semiconductor layer.

7. The photonic integrated apparatus of claim 1, wherein the conductive layer comprises a conductive via.

8. The photonic integrated apparatus of claim 1, wherein the conductive layer comprises:
a first conductive layer covering a plurality of surfaces of the tunneling barrier layer; and
a second conductive layer provided on a portion of a surface of the first conductive layer.

9. The photonic integrated apparatus of claim 8, wherein a contact area between the first conductive layer and the tunneling barrier layer is equal to a contact area between the tunneling barrier layer and the second semiconductor layer.

10. The photonic integrated apparatus of claim 1, wherein the first semiconductor layer comprises:
a lightly doped region; and
a first doped region and a second doped region apart from each other with the lightly doped region therebetween.

11. The photonic integrated apparatus of claim 10, wherein the lightly doped region overlaps the second semiconductor layer in a direction in which the second semiconductor layer is stacked on the first semiconductor layer.

12. The photonic integrated apparatus of claim 10, wherein a same voltage is applied to the first doped region and the second doped region.

13. The photonic integrated apparatus of claim 1, wherein the second semiconductor layer comprises at least one of Ge or GeₓSn₁₋ₓ (0<x<1).

14. The photonic integrated apparatus of claim 1, wherein the conductive layer comprises at least one of a metal, an alloy, a metal oxide, a metal nitride, or a silicide.

15. The photonic integrated apparatus of claim 1, wherein a difference between a conduction band energy level of the tunneling barrier layer and an electron affinity of the second semiconductor layer is less than or equal to 0.5 eV.

16. The photonic integrated apparatus of claim 1, wherein a bandgap energy of the tunneling barrier layer is greater than a bandgap energy of the second semiconductor layer.

17. The photonic integrated apparatus of claim 1, wherein a bandgap energy of the tunneling barrier layer is greater than or equal to 2 eV.

18. The photonic integrated apparatus of claim 1, wherein a thickness of the tunneling barrier layer is greater than or equal to 1 nm.

19. The photonic integrated apparatus of claim 1, wherein the tunneling barrier layer comprises at least one of a metal oxide or a silicon oxide.

20. The photonic integrated apparatus of claim 19, wherein the metal oxide comprises at least one of TiO₂, TiO₂₋ₓ (0<x<1), TiO, Ti₂O, Ti₃O, Ti₂O₃, TiₙO₂ₙ₋₁ (where n is an integer from 3 to 9), SnO₂, ZnO, WO₃, Nb₂O₅, BaSnO₃, Zn₂SnO₄, SrTiO₃, BaTiO₃, Zn₂Ti₃O₈, SiO₂, Al₂O₃, HfO₂, MgO, MoO₃, Fe₂O₃, Ta₂O₅, TaON, or In₂O₃.
